(19) United States
(12) Patent Application Publication
(10) Pub. No.: US 2022/0352281 A1
(43) Pub. Date: Nov. 3, 2022

(54) DISPLAY APPARATUS

(71) Applicant: Samsung Display Co., Ltd., Yongin-si (KR)

(72) Inventors: Hyuneok Shin, Yongin-si (KR); Gyungmin Baek, Yongin-si (KR); Shinil Choi, Yongin-si (KR)

(21) Appl. No.: 17/715,700

(22) Filed: Apr. 7, 2022

(30) Foreign Application Priority Data
Apr. 29, 2021 (KR) 10-2021-0055948

(51) Int. Cl. H01L 27/32; H01L 27/12; H01L 51/52

(52) U.S. Cl. CPC H01L 27/3262; H01L 27/1225; H01L 51/5253

(57) ABSTRACT

A display apparatus includes a substrate, a first thin-film transistor arranged on the substrate and including a first semiconductor layer and a first gate electrode, the first semiconductor layer including silicon, and the first gate electrode overlapping the first semiconductor layer, a second thin-film transistor arranged on the substrate and including a second semiconductor layer and a second gate electrode, the second semiconductor layer including an oxide semiconductor, and the second gate electrode overlapping the second semiconductor layer, and a display element electrically connected to the first thin-film transistor, wherein the second gate electrode has a structure in which a lower layer and an upper layer are stacked, the upper layer including a material different from that of the lower layer, and an end of an upper surface of the lower layer is apart by a first separation distance from an end of a lower surface of the upper layer.

### CROSS-REFERENCE TO RELATED APPLICATION

This application is based on and claims priority under 35 U.S.C. § 119 to Korean Patent Application No. 10-2021-0055948, filed on Apr. 29, 2021, in the Korean Intellectual Property Office, the disclosure of which is incorporated by reference herein in its entirety.

### BACKGROUND

### 1. Field

The present disclosure relates to a display apparatus. More particularly, the present disclosure relates to a display apparatus capable of providing a high-quality image.

### 2. Description of the Related Art

Recently, the usage of display apparatuses has diversified. In addition, as display apparatuses have become thinner and lighter, their range of use has gradually been extended. As display apparatuses are utilized in various fields, demand for display apparatuses that provide high-quality images increases.

### SUMMARY

One or more embodiments include a display apparatus that may provide a high-quality image. However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first thin-film transistor arranged on the substrate and including a first semiconductor layer and a first gate electrode, the first semiconductor layer including silicon, and the first gate electrode overlapping the first semiconductor layer, a second thin-film transistor arranged on the substrate and including a second semiconductor layer and a second gate electrode, the second semiconductor layer including an oxide semiconductor, and the second gate electrode overlapping the second semiconductor layer, and a display element electrically connected to the first thin-film transistor, wherein the second gate electrode has a structure in which a lower layer and an upper layer are stacked in a thickness direction, the upper layer including a material different from a material of the lower layer, wherein an end of an upper surface of the lower layer is spaced apart by a first separation distance in a first direction perpendicular to the thickness direction from an end of a lower surface of the upper layer, wherein a second gate insulating layer patterned is between the second semiconductor layer and the second gate electrode, and wherein an end of an upper surface of the second gate insulating layer is spaced apart by a second separation distance in the first direction from an end of a lower surface of the lower layer.

The second separation distance may have a value in a range of about 0.2 to about 5 times the first separation distance.

The second separation distance may have a value in a range of about 0.1 μm to about 1 μm.

The first separation distance may have a value in a range of about 0.2 μm to about 0.5 μm.

A thickness of the upper layer in the thickness direction may be greater than a thickness of the lower layer.

An etch rate of the upper layer may be greater than an etch rate of the lower layer.

The upper layer may include copper (Cu) and the lower layer may include titanium (Ti).

The first gate electrode may include a single layer of a copper alloy and include at least one of silver (Ag), calcium (Ca), and zinc (Zn) in addition to copper (Cu).

The first gate electrode may include a first layer and a second layer that are stacked in the thickness direction, the second layer is arranged on the first layer, the first layer may include a copper alloy or indium zinc oxide (InZnO), and the second layer may include copper.

An end of an upper surface of the first layer may contact an end of a lower surface of the second layer.

An end of an upper surface of the first layer may be spaced apart by a third separation distance in the first direction from an end of a lower surface of the second layer, and the third separation distance may be less than the first separation distance.

The third separation distance may have a value in a range of about 0 μm to about 0.1 μm.

The display apparatus may further include a storage capacitor overlapping the first thin-film transistor and including a first electrode and a second electrode, the second electrode arranged on the first electrode, wherein the second electrode may include a third layer and a fourth layer that are stacked in the thickness direction, the fourth layer arranged on the third layer.

The third layer may include a copper alloy or indium zinc oxide (InZnO), and the fourth layer may include copper.

The display apparatus may further include a lower conductive layer arranged between the substrate and the first thin-film transistor, wherein the lower conductive layer may overlap at least a portion of the first semiconductor layer.

The display apparatus may further include a thin-film encapsulation layer covering the display element and including a first inorganic encapsulation layer, an organic encapsulation layer, and a second inorganic encapsulation layer that are sequentially stacked in the thickness direction, wherein the substrate may include a first base layer, a first inorganic barrier layer, a second base layer, and a second inorganic barrier layer that are sequentially stacked in the thickness direction.

According to one or more embodiments, a display apparatus includes a substrate, a thin-film transistor arranged on the substrate and including an oxide semiconductor layer and a gate electrode, the oxide semiconductor layer including an oxide semiconductor, and the gate electrode overlapping the oxide semiconductor layer, and a display element electrically connected to the thin-film transistor, wherein the gate electrode has a structure in which a lower layer and an upper layer are stacked in a thickness direction, the upper layer including a material different from a material of the lower layer, and an end of an upper surface of the lower layer is apart by a first separation distance from an end of a lower surface of the upper layer, a gate insulating layer patterned is arranged between the oxide semiconductor layer and the gate electrode, and an end of an upper surface of the gate insulating layer is spaced apart by a second separation distance in a first direction perpendicular to the thickness direction from an end of a lower surface of the lower layer.

The second separation distance may have a value in a range of about 0.2 to about 5 times the first separation distance.

The second separation distance may be greater than the first separation distance.

The upper layer may include copper (Cu) and the lower layer may include titanium (Ti).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view of a display apparatus according to an embodiment;

FIG. 2 is an equivalent circuit diagram of a pixel circuit and an organic light-emitting diode as a display element connected thereto, the pixel circuit driving a pixel according to an embodiment;

FIG. 3 is a cross-sectional view of the display apparatus of FIG. 1 taken along line I-I′ of FIG. 1;

FIG. 4 is an enlarged view of region II of FIG. 3, showing a second thin-film transistor including an oxide semiconductor;

FIG. 5 is a plan layout of a portion corresponding to FIG. 4;

FIGS. 6A, 6B, and 6C are cross-sectional views showing a method of manufacturing a second thin-film transistor according to an embodiment;

FIG. 7 is a cross-sectional view of a display apparatus according to an embodiment;

FIG. 8 is a cross-sectional view of a display apparatus according to an embodiment;

FIG. 9 is a cross-sectional view of a display apparatus according to an embodiment; and

FIG. 10 is a cross-sectional view of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. For example, since sizes and thicknesses of elements in the drawings are arbitrarily illustrated for convenience of explanation, the disclosure is not limited thereto.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component interposed therebetween.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the present specification, “A and/or B” means A or B, or A and B.

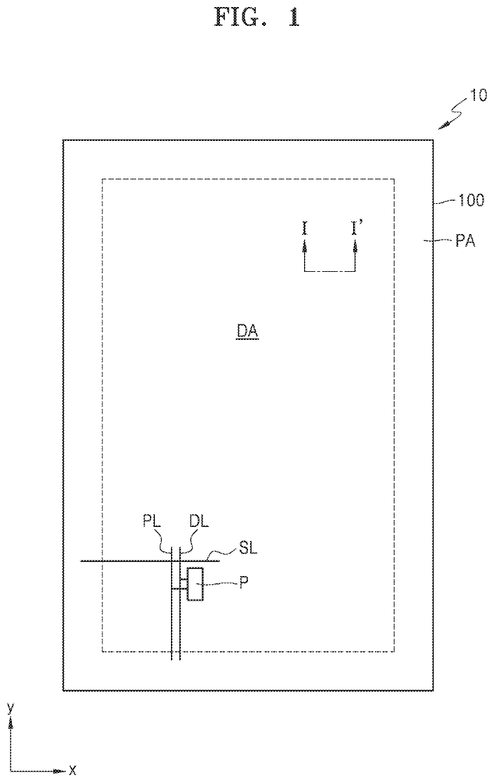

FIG. 1 is a plan view of a display apparatus 10 according to an embodiment.

Referring to FIG. 1, a substrate 100 of the display apparatus 10 may be divided into a display area DA and a peripheral area PA located outside of the display area DA. The display apparatus 10 may display an image by using light emitted from a plurality of pixels P arranged in the display area DA.

Each pixel P may include a display element such as an organic light-emitting diode or an inorganic light-emitting diode and emit, for example, red, green, blue, or white light. That is, each pixel P may be connected to a pixel circuit including a thin-film transistor TFT and a storage capacitor. The pixel circuit may be connected to a scan line SL, a data line DL, and a driving voltage line PL. The data line DL and the driving voltage line PL cross the scan line SL. The scan line SL may extend in an x-direction, and the data line DL and the driving voltage line PL may extend in a y-direction.

As the pixel circuit is driven, each pixel P may emit light, and the display area DA displays a preset image through light emitted from the pixels P. In the present specification, as described above, a pixel P may be defined as an emission area that emits light having one of red, green, blue, and white colors.

The peripheral area PA is a region in which the pixels P are not arranged and does not display an image. A built-in driving circuit portion, a power supply line, a terminal portion, and the like may be arranged in the peripheral area PA, the built-in driving circuit portion being configured to drive the pixels P, a printed circuit board including the driving circuit portion, or a driver integrated circuit (IC) being connected to the terminal portion.

The display apparatus 10 according to an embodiment may include an organic light-emitting display, an inorganic light-emitting display, and a quantum-dot display. Hereinafter, though an organic light-emitting display apparatus is described as an example of a display apparatus according to an embodiment, the display apparatus according to an embodiment is not limited thereto and the characteristics described below are applicable to the various types of display apparatuses described above.

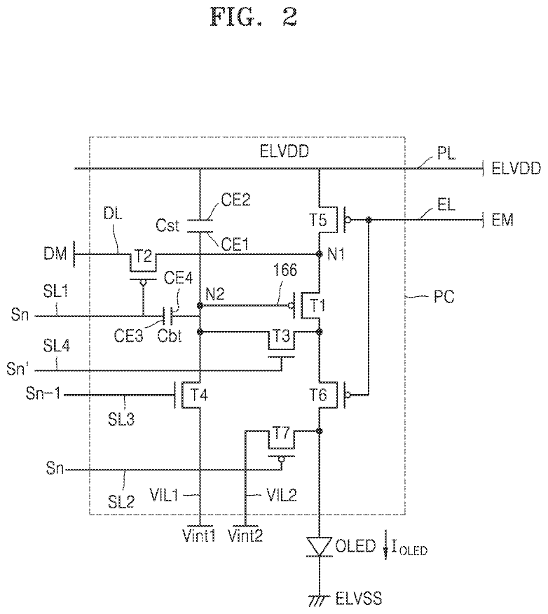

FIG. 2 is an equivalent circuit diagram of a pixel circuit PC and an organic light-emitting diode as a display element connected thereto, the pixel circuit driving a pixel according to an embodiment.

Referring to FIG. 2, the pixel circuit PC includes a plurality of first to seventh transistors T1, T2, T3, T4, T5, T6, and T7, a storage capacitor Cst, and a boosting capacitor Cbt. In addition, the pixel circuit PC is connected to a plurality of signal lines, first and second initialization voltage lines VIL1 and VIL2, and the driving voltage line PL. The signal lines may include a first scan line SL1, a second scan line SL2, a third scan line SL3, a fourth scan line SL4, and an emission control line EL. In another embodiment, at least one of the signal lines, the first and second initialization voltage lines VIL1 and VIL2, and/or the driving voltage line PL may be shared by pixel circuits adjacent to each other.

The driving voltage line PL may be configured to transfer a first power voltage ELVDD to the first transistor T1. The first initialization voltage line VIL1 may be configured to transfer a first initialization voltage Vint1 to the pixel circuit PC, the first initialization voltage Vint1 initializing the first transistor T1. The second initialization voltage line VIL2 may be configured to transfer a second initialization voltage Vint2 to the pixel circuit PC, the second initialization voltage Vint2 initializing an organic light-emitting diode OLED.

The first scan line SL1, the second scan line SL2, the third scan line SL3, the fourth scan line SL4, the emission control line EL, and the first and second initialization voltage lines VIL1 and VIL2 may extend in a first direction (an x-direction) and be apart from each other on each row. The data line DL and the driving voltage line PL may extend in a second direction (a y-direction) and be apart from each other on each column.

It is shown in FIG. 2 that the third transistor T3 and the fourth transistor T4 from among the first to seventh transistors T1, T2, T3, T4, T5, T6, and T7 are implemented as n-channel metal oxide semiconductor field-effect transistors (MOSFET), and the rest of the transistors are implemented as p-channel metal oxide semiconductor field-effect transistors (MOSFET).

The first transistor T1 is connected to the driving voltage line PL through the fifth transistor T5 and electrically connected to the organic light-emitting diode OLED through the sixth transistor T6. The first transistor T1 serves as a driving transistor and is configured to receive a data signal Dm according to a switching operation of the second transistor T2 and supply a driving current I_{OLED} to the organic light-emitting diode OLED.

The second transistor T2 serving as a switching transistor is connected to the first scan line SL1 and the data line DL, and is also connected to the driving voltage line PL through the fifth transistor T5. The second transistor T2 is turned on according to a first scan signal Sn transferred through the first scan line SL1 and performs a switching operation of transferring a data signal Dm to a node N1, the data signal Dm being transferred through the data line DL.

The third transistor T3 is a compensation transistor, is connected to the fourth scan line SL4 and connected to the organic light-emitting diode OLED through the sixth transistor T6. The third transistor T3 is turned on according to a fourth scan signal Sn′ and diode-connects the first transistor T1, the fourth scan signal Sn′ being transferred through the fourth scan line SL4.

The fourth transistor T4 is a first initialization transistor, is connected to the third scan line SL3, which is a previous scan line, and the first initialization voltage line VIL1, is turned on according to a third scan signal Sn−1, and initializes the voltage of a gate electrode of the first transistor T1 by transferring the first initialization voltage Vint1 to the gate electrode of the first transistor T1, the third scan signal Sn−1 being a previous scan signal transferred through the third scan line SL3, and the first initialization voltage Vint1 being from the first initialization voltage line VIL1.

The fifth transistor T5 may be an operation control transistor, and the sixth transistor T6 may be an emission control transistor. The fifth transistor T5 and the sixth transistor T6 are connected to the emission control line EL and simultaneously turned on according to an emission control signal EM to form a current path such that the driving current I_{OLED} flows in a direction from the driving voltage line PL to the organic light-emitting diode OLED, the emission control signal EM being transferred through the emission control line EL.

The seventh transistor T7 is a second initialization transistor, is connected to the second scan line SL2, which is a next scan line SL2, and the second initialization voltage line VIL2, turned on according to a second scan signal Sn+1, and initializes the organic light-emitting diode OLED by transferring the second initialization voltage Vint2 to the organic light-emitting diode OLED, the second scan signal Sn+1 being a next scan signal transferred through the second scan line SL2, and the second initialization voltage Vint2 being from the second initialization voltage line VIL2. The seventh transistor T7 may be omitted.

The storage capacitor Cst includes a first electrode CE1 and a second electrode CE2. The first electrode CE1 is connected to the gate electrode of the first transistor T1, and the second electrode CE2 is connected to the driving voltage line PL. The storage capacitor Cst may maintain a voltage applied to the gate electrode of the first transistor T1 by storing and maintaining a voltage corresponding to a difference between voltages of two opposite ends of the driving voltage line PL and the gate electrode of the first transistor T1.

The boosting capacitor Cbt includes a third electrode CE3 and a fourth electrode CE4. The third electrode CE3 is connected to the first scan line SL1 and a gate electrode of the second transistor T2. The fourth electrode CE4 is connected to the gate electrode of the first transistor T1 and the first electrode CE1 of the storage capacitor Cst. In the case where a first scan signal Sn of the first scan line SL1 is a voltage of turning off the second transistor T2, the boosting capacitor Cbt may reduce a voltage (a black voltage) that displays black by raising the voltage of a node N2.

The organic light-emitting diode OLED may include a pixel electrode and an opposite electrode, and the opposite electrode may receive a second power voltage ELVSS. The organic light-emitting diode OLED displays an image by receiving the driving current I_{OLED} from the first transistor T1 and emitting light.

A specific operation of the pixel circuit PC according to an embodiment is described below.

During a first initialization period, when a third scan signal Sn−1 is supplied through the third scan line SL3, the fourth transistor T4 is turned on according to the third scan signal Sn−1, and the first transistor T1 is initialized by the first initialization voltage Vint1 supplied from the first initialization voltage line VIL1.

During a data programming period, when a first scan signal Sn and a fourth scan signal Sn′ are respectively supplied through the first scan line SL1 and the fourth scan line SL4, the second transistor T2 and the third transistor T3 are turned on according to the first scan signal Sn and the fourth scan signal Sn′. In this case, the first transistor T1 is diode-connected and forward-biased by the third transistor t3 that is turned on. Then, a voltage in which a threshold voltage Vth of the first transistor T1 is compensated for from a data signal Dm supplied from the data line DL is applied to the gate electrode of the first transistor T1. The first power voltage ELVDD and the compensation voltage are respectively applied to two opposite ends of the storage capacitor Cst, and a charge corresponding to the voltage difference between the two opposite ends is stored in the storage capacitor Cst.

During a light emission period, the fifth transistor T5 and the sixth transistor T6 are turned on according to an emission control signal En supplied from the emission control line EL. The driving current I_{OLED} corresponding to a voltage difference between the voltage of the gate electrode of the first transistor T1 and the first power voltage ELVDD occurs, and the driving current I_{OLED} is supplied to the organic light-emitting diode OLED through the sixth transistor T6.

During a second initialization period, when a second scan signal GP2 is supplied through the second scan line SL2, the seventh transistor T7 is turned on according to the second scan signal GP2, and the organic light-emitting diode OLED is initialized by the second initialization voltage Vint2 supplied from the second initialization voltage line VIL2.

At least some of the first to seventh transistors T1, T2, T3, T4, T5, T6, and T7 may include different types of semiconductor layers. As an example, the first transistor T1 serving as the driving transistor may include a semiconductor layer including silicon, and at least one of the second transistor T2, which is the switching transistor, to the seventh transistor T7 may include an oxide semiconductor layer.

Silicon has excellent mobility and reliability. Accordingly, because the first transistor T1 that directly influences the brightness of the organic light-emitting diode OLED includes a semiconductor layer including silicon, a high-resolution display apparatus may be implemented.

In addition, a transistor including an oxide semiconductor layer has a low off-current and may be driven at low frequencies. Accordingly, because at least one of the rest of transistors, that is, the second to seventh transistors T2, T3, T4, T5, T6, and T7 except for the first transistor T1 includes an oxide semiconductor layer, the power consumption of the display apparatus may be reduced.

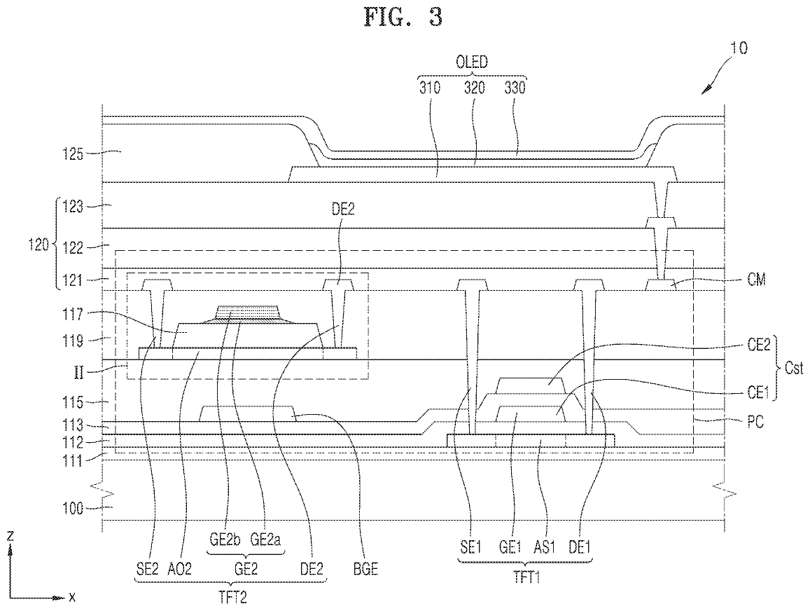

FIG. 3 is a cross-sectional view of the display apparatus taken along line I-I′ of FIG. 1.

Referring to FIG. 3, in the display apparatus according to an embodiment, the pixel circuit PC may be arranged over the substrate 100, and the organic light-emitting diode OLED may be arranged as a display element connected to the pixel circuit PC.

For convenience of description, FIG. 3 shows only a first thin-film transistor TFT1 including a silicon semiconductor, a second thin-film transistor TFT2 including an oxide semiconductor, and a storage capacitor Cst among the configuration of the pixel circuit. The first thin-film transistor TFT1 may be the first transistor T1 of FIG. 2, and the second thin-film transistor TFT2 may be one of the second to seventh transistors T2, T3, T4, T5, T6, and T7.

The first thin-film transistor TFT1 may include a first semiconductor layer AS1 and a first gate electrode GE1 insulated from the first semiconductor layer AS1, the first semiconductor layer AS1 including a silicon semiconductor. The first thin-film transistor TFT1 may include a first source electrode SE1 and/or a first drain electrode DE1 each connected to the first semiconductor layer AS1. The first thin-film transistor TFT1 may serve as a driving thin-film transistor.

The second thin-film transistor TFT2 includes a second semiconductor layer AO2 and a second gate electrode GE2 insulated from the second semiconductor layer AO2, the second semiconductor layer AO2 including an oxide semiconductor. The second thin-film transistor TFT2 may include a second source electrode SE2 and/or a second drain electrode DE2 each connected to the second semiconductor layer AO2. The second thin-film transistor TFT2 may serve as a switching thin-film transistor.

In an embodiment, the first semiconductor layer AS1 of the first thin-film transistor TFT1 serving as the driving thin-film transistor may include polycrystalline silicon having excellent reliability, and the second semiconductor layer AO2 of the second thin-film transistor TFT2 corresponding to the switching thin-film transistor may include an oxide semiconductor having a small leakage current.

Hereinafter, a structure in which elements of the display apparatus 10 are stacked is described.

The substrate 100 may include an insulating material such as glass, quartz, and a polymer resin. The substrate 100 may be a rigid substrate or a flexible substrate that is bendable, foldable, rollable, or flexible. The substrate 100 may have a single-layered structure or a multi-layered structure including the above materials. In the case of the multi-layered structure, the substrate 100 may further include an inorganic layer. In an embodiment, the substrate 100 may have a structure of an organic material/an inorganic material/an organic material.

A buffer layer 111 may be arranged on the substrate 100, may reduce or block the penetration of foreign substance, moisture, or external air from below the substrate 100, and provide a flat surface on the substrate 100. The buffer layer 111 may include an inorganic material such as oxide or nitride, an organic material, or an organic/inorganic composite material, and have a single-layered structure or a multi-layered structure of an inorganic material and an organic material. In an embodiment, the buffer layer 111 may include silicon oxide (SiO₂), silicon nitride (SiNₓ), or silicon oxynitride (SiOₓN_{y}).

The first semiconductor layer AS1 including a silicon semiconductor may be arranged on the buffer layer 111, the first semiconductor layer AS1 including polycrystalline silicon or amorphous silicon. The first semiconductor layer AS1 may include a channel region, a source region, and a drain region, the source region and the drain region being doped with impurities.

A first gate insulating layer 112 may cover the first semiconductor layer AS1. The first gate insulating layer 112 may include an inorganic insulating material such as silicon oxide (SiO₂), silicon nitride (SiNₓ), silicon oxynitride (SiOₓN_{y}), aluminum oxide (Al₂O₃), and titanium oxide (TiO₂). The first gate insulating layer 112 may include a single layer or a multi-layer including the inorganic insulating materials.

A first gate electrode GE1 is arranged on the first gate insulating layer 112 to overlap the first semiconductor layer AS1. The first gate electrode GE1 may include copper (Cu) and a copper (Cu) alloy and include a single layer or a multi-layer. The first gate electrode GE1 may include indium zinc oxide (InZnO), silver (Ag), calcium (Ca), zinc (Zn), magnesium (Mg), and aluminum (Al), titanium (Ti) in addition to copper (Cu). In the case where the first gate electrode GE1 includes a single layer of a copper alloy, impurities to be included may be at least one of Ag, Ca, and Zn. This is for reducing a rise of a resistivity of the first gate electrode GE1 and simultaneously improving adhesion characteristics with an insulating layer thereunder.

A first interlayer insulating layer 113 may cover the first gate electrode GE1. The first interlayer insulating layer 113 may include an inorganic insulating material such as silicon oxide (SiO₂), silicon nitride (SiNₓ), silicon oxynitride (SiOₓN_{y}), aluminum oxide (Al₂O₃), and titanium oxide (TiO₂). The first interlayer insulating layer 113 may include a single layer or a multi-layer including the above inorganic insulating materials.

The storage capacitor Cst may overlap the first gate electrode GE1. The storage capacitor Cst may include the first electrode CE1 and the second electrode CE2. The first interlayer insulating layer 113 may be arranged between the first electrode CE1 and the second electrode CE2. In this case, the first gate electrode GE1 may serve as the first electrode CE1 of the storage capacitor Cst as well as the gate electrode of the first thin-film transistor TFT1. That is, the first gate electrode GE1 and the first electrode CE1 may be one body. The second electrode CE2 is arranged on the first interlayer insulating layer 113 to overlap the first electrode CE1.

A bottom gate electrode BGE may be arranged on the first interlayer insulating layer 113 and may overlap the second thin-film transistor TFT2. The bottom gate electrode BGE may overlap the second semiconductor layer AO2 of the second thin-film transistor TFT2 and apply a gate signal to the second thin-film transistor TFT2. In this case, the second thin-film transistor TFT2 may have a double-gate electrode structure in which gate electrodes are respectively arranged on and under the second semiconductor layer AO2.

The second electrode CE2 of the storage capacitor Cst and the bottom gate electrode BGE may include at least one of copper (Cu) and a copper (Cu) alloy and include a single layer or a multi-layer. The second electrode CE2 and the bottom gate electrode BGE may include InZnO, Ag, Ca, Zn, Mg, Al, and Ti in addition to copper (Cu). In the case where the second electrode CE2 and the bottom gate electrode BGE include a single layer of a copper (Cu) alloy, impurities to be included may be at least one of Ag, Ca, and Zn. This is for reducing a rise of resistivities of the second electrode CE2 and the bottom gate electrode BGE, and simultaneously, for improving adhesive characteristics with an insulating layer thereunder.

In the present embodiment, the first gate electrode GE1, the second electrode CE2, and the bottom gate electrode BGE may include a material having a resistivity of about 1.8 μΩcm to about 2.2 μΩcm.

As an example, in the case where the first gate electrode GE1, the second electrode CE2, and the bottom gate electrode BGE include a material having a resistivity of 12 μΩcm or more such as molybdenum (Mo), an RC delay phenomenon may occur while the display apparatus is driven at high speeds. In the case where molybdenum (Mo) is deposited thick to reduce the RC delay phenomenon, defects during a process such as warping of the substrate 100 may occur.

In the present embodiment, because a material having a small resistivity is employed as the first gate electrode GE1, the second electrode CE2, and the bottom gate electrode BGE, the display apparatus may be driven at high speeds even when the first gate electrode GE1, the second electrode CE2, and the bottom gate electrode BGE are formed thin. In an embodiment, the thicknesses of the first gate electrode GE1, the second electrode CE2, and the bottom gate electrode BGE in the z-direction may be in the range of about 1000 Å to about 10000 Å.

In the case where the first gate electrode GE1 includes a single layer, the first gate electrode GE1 may include a copper (Cu) alloy. In the case where the first gate electrode GE1 includes a single layer of pure copper (Cu) instead of an alloy, adhesive characteristics with the first gate insulating layer 112 may not be good.

In an embodiment, to improve adhesive characteristics with the first gate insulating layer 112, and simultaneously, for the value of the resistivity to satisfy the range of about 1.8 μΩcm to about 2.2 μΩcm, the first gate electrode GE1 may include a copper (Cu) alloy, and impurities to be included in the copper alloy may include one of Ag, Ca, and Zn. In the case where the impurities included in the copper alloy is one of Ag, Ca, and Zn, when the impurities are added by 1 atomic %, an increase in the resistivity may be less than 0.5 μΩcm.

Likewise, in the case where the second electrode CE2 and the bottom gate electrode BGE include a single layer, the second electrode CE2 and the bottom gate electrode BGE may include a copper alloy and impurities included in the copper alloy may be one of Ag, Ca, and Zn.

The first interlayer insulating layer 113 may include an inorganic material including oxide or nitride. As an example, the first interlayer insulating layer 113 may include at least one of silicon oxide (SiO₂), silicon nitride (SiNₓ), silicon oxynitride (SiOₓN_{y}), aluminum oxide (Al₂O₃), and titanium oxide (TiO₂).

A second interlayer insulating layer 115 may cover the second electrode CE2 of the storage capacitor Cst and the bottom gate electrode BGE. The second interlayer insulating layer 115 may include at least one of silicon oxide (SiO₂), silicon nitride (SiNₓ), silicon oxynitride (SiOₓN_{y}), aluminum oxide (Al₂O₃), and titanium oxide (TiO₂). The second interlayer insulating layer 115 may include a single layer or a multi-layer including the above inorganic insulating materials.

The second semiconductor layer AO2 may be arranged on the second interlayer insulating layer 115, the second semiconductor layer AO2 including an oxide semiconductor. The second semiconductor layer AO2 may include a channel region, a source region, and a drain region, the source region and the drain region being respectively arranged on two opposite sides of the channel region. The second semiconductor layer AO2 may include an oxide of at least one of indium (In), gallium (Ga), stannum (Sn), zirconium (Zr), hafnium (Hf), titanium (Ti), and zinc (Zn). In an embodiment, the second semiconductor layer AO2 may include a Zn-oxide-based material and include Zn-oxide, In—Zn oxide, and Ga—In—Zn oxide. In an embodiment, the second semiconductor layer AO2 may include an IGZO (In—Ga—Zn—O) semiconductor containing metal such as indium (In) and gallium (Ga) in ZnO.

The source region and the drain region of the second semiconductor layer AO2 may be formed by adjusting carrier concentration of an oxide semiconductor and making the source region and the drain region conductive. For example, the source region and the drain region of the second semiconductor layer AO2 may be formed by increasing carrier concentration through plasma treatment that uses a hydrogen (H)-based gas, a fluorine (F)-based gas, or a combination of these performed on the oxide semiconductor.

The second gate electrode GE2 may be arranged over the second semiconductor layer AO2. A second gate insulating layer 117 may be arranged between the second semiconductor layer AO2 and the second gate electrode GE2. The second gate electrode GE2 may be arranged to the second semiconductor layer AO2 and is insulated from the second semiconductor layer AO2 by the second gate insulating layer 117.

The second gate electrode GE2 may include a lower layer GE2a and an upper layer GE2b that are stacked and include different materials. The upper layer GE2ba and the lower layer GE2a may include materials having different etching ratios under the same etching condition. In an embodiment, the upper layer GE2b may include at least one of copper (Cu) and a copper (Cu) alloy. The upper layer GE2b may include Ag, Zn, Mg, Al, Ca, and Ti in addition to copper (Cu). The lower layer GE2a may include at least one of titanium (Ti) and a titanium (Ti) alloy. The lower layer GE2a may include molybdenum (Mo) in addition to titanium (Ti).

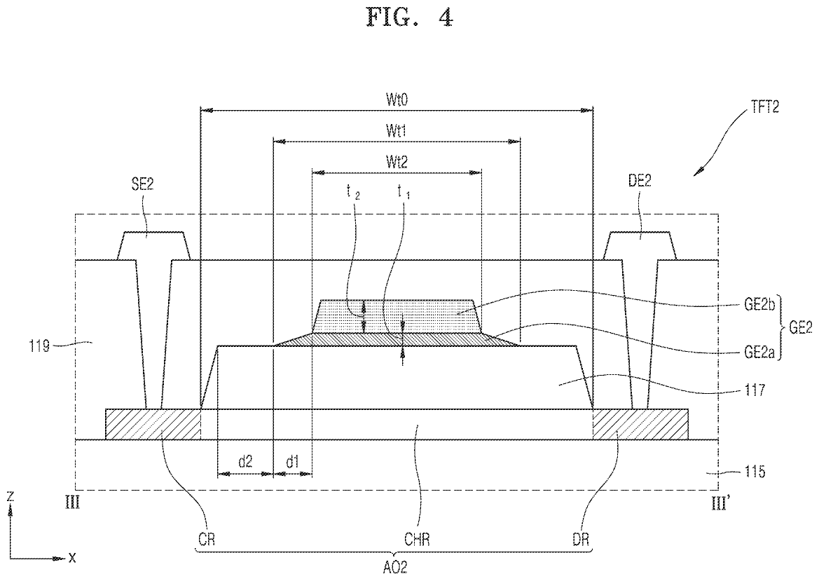

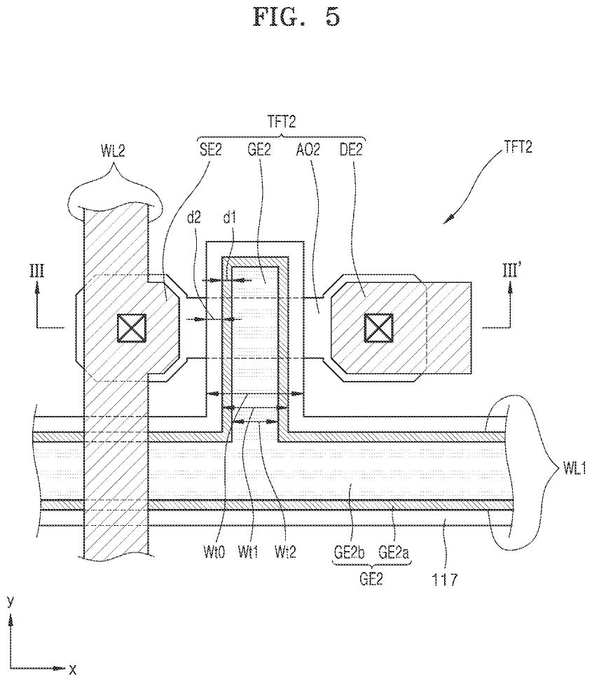

In an embodiment, the end of the upper surface of the lower layer GE2a of the second gate electrode GE2 may be spaced apart from the end of the lower surface of the upper layer GE2b of the second gate electrode GE2. The lower layer GE2a and the upper layer GE2b may be formed with a step difference having a step shape. A portion of the upper surface of the lower layer GE2a may not be covered by the upper layer GE2b. That is, some portions of the lower layer GE2a are not covered by the upper layer GE2b because the width of the lower layer GE2a in the x-direction may be greater than the width of the upper layer GE2b in the x-direction. This is described below with reference to FIGS. 4 and 5.

The second gate insulating layer 117 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The second gate insulating layer 117 may include a single layer or a multi-layer including the above inorganic insulating materials.

The second gate insulating layer 117 may not be entirely formed over the substrate 100 and be patterned similar to the shape of the second gate electrode GE2. However, the end of the upper surface of the second gate insulating layer 117 may be spaced apart from the end of the lower surface of the second gate electrode GE2. Some portions of the upper surface of the second gate insulating layer 117 may not be covered by the second gate electrode GE2 because the width of the second gate insulating layer 117 in the x-direction may be greater than the width of the second gate electrode GE2 in the x-direction.

The second gate insulating layer 117 does not cover two opposite ends of the second semiconductor layer AO2 and may expose the source region and the drain region of the second semiconductor layer AO2. That is, the width of the second semiconductor layer AO2 in the x-direction may be greater than the width of the second gate insulating layer 117 in the x-direction.

A third interlayer insulating layer 119 may be arranged on the second gate electrode GE2, the second gate insulating layer 117, and the second semiconductor layer AO2. The first source electrode SE1 and/or the first drain electrode DE1, and the second source electrode SE2 and/or the second drain electrode DE2 may be arranged on the third interlayer insulating layer 119. The first source electrode SE1 and/or the first drain electrode DE1 may be connected to the first semiconductor layer AS1 through contact holes penetrating the third interlayer insulating layer 119, the second interlayer insulating layer 115, the first interlayer insulating layer 113, and the first gate insulating layer 112, and the second source electrode SE2 and/or the second drain electrode DE2 may be connected to the second semiconductor layer AO2 through contact holes penetrating the third interlayer insulating layer 119. In addition, a conductive layer CM may be arranged on the third interlayer insulating layer 119. The conductive layer CM may be a connection electrode that electrically connects one electrode of one of the plurality of transistors of the pixel circuit PC to a pixel electrode 310.

In addition, a data line and a driving voltage line may be arranged on the third interlayer insulating layer 119, the data line being configured to transfer a data signal, and the driving voltage line being configured to transfer a driving voltage. The source electrode SE1, the first drain electrode DE1, the second source electrode SE2, or the second drain electrode DE2 may be connected to the data line or the driving voltage line directly or through other transistors.

The third interlayer insulating layer 119 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The third interlayer insulating layer 119 may include a single layer or a multi-layer including the inorganic insulating material.

The source electrode SE1, the first drain electrode DE1, the second source electrode SE2, and the second drain electrode DE2 may include a material having a high conductivity such as metal and a conductive oxide. As an example, the source electrode SE1, the first drain electrode DE1, the second source electrode SE2, and the second drain electrode DE2 may include a single or a multi-layer including at least one of aluminum (Al), copper (Cu), and titanium (Ti). In an embodiment, the source electrode SE1, the first drain electrode DE1, the second source electrode SE2, and the second drain electrode DE2 may include a triple layer of titanium, aluminum, and titanium (Ti/Al/Ti) that are sequentially stacked.

An organic insulating layer 120 is arranged on the source electrode SE1, the first drain electrode DE1, the second source electrode SE2, and the second drain electrode DE2. The organic insulating layer 120 may include a single layer or a multi-layer. In an embodiment, the organic insulating layer 120 may include a first organic insulating layer 121, a second organic insulating layer 122, a third organic insulating layer 123 that are stacked. In this case, various wirings WL may be arranged between the first organic insulating layer 121 and the second organic insulating layer 122, and between the second organic insulating layer 122 and the third organic insulating layer 123. Accordingly, it may be advantageous in high integration.

The organic insulating layer 120 may include a general-purpose polymer such as polyimide, polystyrene (PS), polycarbonate, benzocyclobutene (BCB), hexamethyldisiloxane (HMDSO), and polymethylmethacrylate (PMMA), polymer derivatives having a phenol-based group, an acryl-based polymer, an imide-based polymer, an aryl ether-based polymer, an amide-based polymer, a fluorine-based polymer, a p-xylene-based polymer, or a vinyl alcohol-based polymer.

Alternatively, the organic insulating layer 120 may include a siloxane-based organic material. The siloxane-based organic material may include hexamethyldisiloxane, octamethyltrisiloxane, decamethyltetrasiloxane, dodecamethylpentasiloxane, and polydimethylsiloxane. The organic insulating layer 120 may serve as a protection layer covering thin-film transistors. All of the first organic insulating layer 121, the second organic insulating layer 122, and the third organic insulating layer 123 may include the same material, or at least one of the first organic insulating layer 121, the second organic insulating layer 122, and the third organic insulating layer 123 may include a different material. However, various modifications may be made.

The organic light-emitting diode OLED may be arranged on the organic insulating layer 120, the organic light-emitting diode OLED including the pixel electrode 310, an opposite electrode 330, and an intermediate layer 320. The intermediate layer 320 may be arranged between the pixel electrode 310 and the opposite electrode 330 and may include an emission layer.

The pixel electrode 310 may be electrically connected to the conductive layer CM through a contact hole defined in the organic insulating layer 120 and connected to the thin-film transistors of the pixel circuit PC through the conductive layer CM. The pixel electrode 310 may be directly connected to the first thin-film transistor TFT1 or indirectly connected to the first thin-film transistor TFT1 through another thin-film transistor (not shown) configured to control light emission.

The pixel electrode 310 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 310 may include a reflective layer including silver (Ag), magnesium (Mg), aluminum (Al), or a compound thereof. As an example, the pixel electrode 310 may have a structure including a layer on/under the reflective layer, the layer including ITO, IZO, ZnO, or In₂O₃. In this case, the pixel electrode 310 may have a structure of ITO/Ag/ITO that are stacked.

A pixel-defining layer 125 may be arranged on the pixel electrode 310. The pixel-defining layer 125 covers the edges of the pixel electrode 310 and defines the pixel by including an opening that exposes the central portion of the pixel electrode 310. In addition, the pixel-defining layer 125 may prevent an arc and the like from occurring at the edges of the pixel electrode 310 by increasing a distance between the edges of the pixel electrode 310 and the opposite electrode 330 over the pixel electrode 310. The pixel-defining layer 125 may include an organic insulating material such as polyimide, polyamide, an acrylic resin, a benzocyclobutene, hexamethyldisiloxane (HMDSO), and a phenolic resin and be formed through spin coating and the like.

The intermediate layer 320 of the organic light-emitting diode OLED may include a low-molecular weight material or a polymer material and emit red, green, blue, or white light. In the case where the intermediate layer 320 includes a low molecular weight material, the intermediate layer 220 may have a structure in which a hole injection layer (HIL), a hole transport layer (HTL), an emission layer (EML), an electron transport layer (ETL), an electron injection layer (EIL), etc. are stacked in a single or composite configuration. The intermediate layer 220 may include various organic materials such as copper phthalocyanine (CuPc), N, N′-Di (naphthalene-1-yl)-N, N′-diphenyl-benzidine (NPB), and tris-8-hydroxyquinoline aluminum (Alq3). These layers may be formed by vacuum deposition.

In the case where the intermediate layer 320 includes a polymer material, the intermediate layer 320 may have a structure including an HTL and an EML. In this case, the HTL may include poly (3, 4-ethylenedioxythiophene) (PEDOT), and the EML may include a polymer material such as a polyphenylene vinylene (PPV)-based material and a polyfluorene-based material. The intermediate layer 320 may be formed through screen printing, inkjet printing, or laser induced thermal imaging (LITI).

The intermediate layer 320 is not limited thereto and may have various structures. In addition, the intermediate layer 320 may include one body cover a plurality of pixel electrodes 310 or include a layer patterned to correspond to each of the plurality of pixel electrodes 310.

The opposite electrode 330 is arranged on the intermediate layer 320. The opposite electrode 330 may include a conductive material having a small work function. As an example, the opposite electrode 330 may include a (semi) transparent layer including silver (Ag), magnesium (Mg), aluminum (Al), platinum (Pt), lithium (Li), calcium (Ca), or an alloy thereof. Alternatively, the opposite electrode 330 may include a layer on the (semi) transparent layer including the above material, the layer including ITO, IZO, ZnO, or In₂O₃. The opposite electrode 330 may be formed as one body over the plurality of organic light-emitting diodes OLED and may correspond to the plurality of pixel electrodes 310.

FIG. 4 is an enlarged view of region II of FIG. 3, showing the second thin-film transistor TFT2 including an oxide semiconductor. FIG. 5 is a plan layout of a portion corresponding to FIG. 4.

Referring to FIGS. 4 and 5, the display apparatus according to an embodiment is arranged on a substrate. The display apparatus includes the second semiconductor AO2 and the second gate electrode GE2 that overlaps the second semiconductor AO2, the second semiconductor AO2 including an oxide semiconductor. The second gate electrode GE2 has a structure in which the lower layer GE2a and the upper layer GE2b that are stacked. The end of the upper surface of the lower layer GE2a is spaced apart by a first separation distance d1 from the end of the lower surface of the upper layer GE2b. Here, the ‘lower surface’ may denote a surface close to the substrate, and the ‘upper surface’ may denote a surface away from the substrate.

In addition, in an embodiment, the second gate insulating layer 117 may be arranged between the second semiconductor layer AO2 of the second thin-film transistor TFT2 and the second gate electrode GE2. The end of the upper surface of the second gate insulating layer 117 may be spaced apart by a second separation distance d2 from the end of the lower surface of the second gate electrode GE2.

The second thin-film transistor TFT2 may include the second semiconductor layer AO2, the second source electrode SE2, the second drain electrode DE2, and the second gate electrode GE2. The second semiconductor layer AO2 may include an oxide semiconductor.

The second semiconductor layer AO2 may include a channel region CHR, a source region SR, and a drain region DR. The source region SR and the drain region DR may be disposed on two opposite sides of the channel region CHR. The source region SR and the drain region DR may be regions that are made conductive by increasing carrier concentration in the second semiconductor layer AO2. The making conductive may be performed through plasma treatment on the second semiconductor layer AO2. Accordingly, the carrier concentration of the source region SR and the drain region DR may be higher than the carrier concentration of the channel region CHR.

The second gate insulating layer 117 may be arranged between the second semiconductor layer AO2 and the second gate electrode GE2. Though the second gate insulating layer 117 is patterned similar to the shape of the second gate electrode GE2, the second gate insulating layer 117 may have an area greater than that of the second gate electrode GE2. The lateral surface of the second gate insulating layer 117 may be covered by the third interlayer insulating layer 119. The second gate insulating layer 117 may cover the channel region CHR and expose the source region SR and the drain region DR.

A width Wt0 of the lower surface of the second gate insulating layer 117 in the-direction may be greater than a width Wt1 of the lower surface of the second gate electrode GE2 in the x-direction. Through this structure, the source region SR and the drain region DR may be made conductive without a separate mask process, and the length of the channel region CHR may be prevented from being reduced.

In the case where the area or the width Wt0 of the second gate insulating layer 117 is the same as the area of the second gate electrode GE2, while the source region SR and the drain region DR are made conductive, the region being conductive may extend below the second gate electrode GE2 and a short-channel may be formed. The forming of the short-channel may cause an electric field to be concentrated on the source region SR and the drain region DR, and thus, may act as a reason of defects in elements.

In the present embodiment, because the width Wt0 of the lower surface of the second gate insulating layer 117 is greater than the width Wt1 of the lower surface of the second gate electrode GE2, the reliability of the second thin-film transistor TFT2 may be secured. In an embodiment, the second separation distance d2 may be in the range of about 0.1 μm to about 1 μm. The second separation distance d2 may be a separation distance between the end of the upper surface of the second gate insulating layer 117 and the end of the lower surface of the second gate electrode GE2. In an embodiment, the second separation distance d2 may be a value of about 0.2 to about 5 times the first separation distance d1. In an embodiment, the second separation distance d2 may be greater than the first separation distance d1.

The width Wt0 of the lower surface of the second gate insulating layer 117 may be greater by about 0.2 μm to about 2 μm than the width Wt1 of the lower surface of the second gate electrode GE2.

In an embodiment, the second gate electrode GE2 may include the lower layer GE2a and the upper layer GE2b that are stacked and have different materials. As an example, the upper layer GE2b and the lower layer GE2a may include materials having different etching ratios. In an embodiment, under the same etching condition, an etching ratio of the upper layer GE2b to the lower layer GE2a may be about 10:1.

In an embodiment, the upper layer GE2b may include copper (Cu) and a copper (Cu) alloy. The upper layer GE2b may include at least one of Ag, Zn, Mg, Al, Ca, Ti in addition to copper (Cu). The lower layer GE2a may include titanium (Ti) and a titanium (Ti) alloy. The lower layer GE2a may include molybdenum (Mo) in addition to titanium (Ti).

The area of the lower layer GE2a is greater than the area of the upper layer GE2b. To express this, it is shown in FIG. 4 that the width Wt1 of the lower surface of the lower layer GE2a in the x-direction is greater than a width Wt2 of the lower surface of the upper layer GE2b in the x-direction. The end of the upper surface of the lower layer GE2a is spaced apart by the first separation distance d1 from the end of the lower surface of the upper layer GE2b.

The upper surface of the lower layer GE2a exposed by the upper layer GE2b may be defined as a ‘tail of the lower layer GE2a’. The tail of the lower layer GE2a may be a configuration for forming the width Wt0 of the second gate insulating layer 117 greater than the width Wt1 of the second gate electrode GE2 during one mask process, and simultaneously a configuration for preventing a region being conductive from extending to the channel region CHR during a process of making the source region SR and the drain region DR conductive.

The length of the tail of the lower layer GE2a, that is, the first separation distance d1 may be in the range of about 0.2 μm to about 0.5 μm. In the case where the first separation distance d1 is 0.2 μm or less, it may be difficult to form the desired width Wt0 of the second gate insulating layer 117. In the case where the first separation distance d1 is 0.5 μm or more, deterioration of the second thin-film transistor TFT2 may occur. The width Wt1 of the lower surface of the lower layer GE2a may be greater by about 0.4 μm to about 1 μm than the width Wt2 of the lower surface of the upper layer GE2b.

A thickness t1 of the lower layer GE2a in the center thereof may be in the range of about 50 Å to about 500 Å. In the case where the lower layer GE2a is deposited to a thickness equal to or less than 50 Å, defects may occur during the process. In the case where the lower layer GE2a is deposited to a thickness greater than 500 Å or more, the length of the tail of the lower layer GE2a becomes 0.5 μm or more, and deterioration of the second thin-film transistor TFT2 may occur. The tail of the lower layer GE2a may have a thickness gradually reducing toward an edge thereof. That is, the thickness t1 of the central portion of the lower layer GE2a may be greater than the thickness of the edge thereof.

The thickness t2 of the upper layer GE2b in a thickness thereof may be about 3000 Å to about 4000 Å. The upper layer GE2b may include a material having a resistivity less than that of the lower layer GE2a. Because the thickness t2 of the upper layer GE2b including a material having a small resistivity is greater than the thickness t1 of the lower layer GE2a, the second gate electrode GE2 may implement a smaller resistance.

Referring to FIG. 5, the second thin-film transistor TFT2 may be arranged over the substrate and electrically connected to a first wiring WL1 and a second wiring WL2, the first wiring WL1 extending in the x-direction, and the second wiring WL2 extending in the y-direction. In an embodiment, the second gate electrode GE2 may be provided as a region protruding from the first wiring WL1. As an example, the second gate electrode GE2 may protrude in the y-direction. That is, the first wiring WL1 and the second gate electrode GE2 may be provided as one body. The first wiring WL1 may be a scan line configured to transfer a scan signal.

The second source electrode SE2 may be provided as a portion of the second wiring WL2 extending in the y-direction. The second source electrode SE2 may be connected to the source region of the second semiconductor layer AO2 through a contact hole CNT. The second drain electrode DE2 may be arranged on the same layer as the second source electrode SE2 and connected to the drain region of the second semiconductor layer AO2 through a contact hole.

The second gate insulating layer 117 may be patterned in a shape similar to those of the first wiring WL1 and the second gate electrode GE2. The area of the second gate insulating layer 117 may be greater than the areas of the first wiring WL1 and the second gate electrode GE2. In a plan view, the edge of the second gate insulating layer 117 may be apart by the second separation distance d2 outward with respect to the edges of the first wiring WL1 and the second gate electrode GE2. The edge of the second gate insulating layer 117 may surround the edges of the first wiring WL1 and the second gate electrode GE2.

The area of the lower layer GE2a of the second gate electrode GE2 may be greater than the area of the upper layer GE2b. In a plan view, at least a portion of the edge of the lower layer GE2a may be apart by the first separation distance d1 outward with respect to at least a portion of the edge of the upper layer GE2b. The edge of the lower layer GE2a may surround at least a portion of the edges of the upper layer GE2b.

Though it is shown in FIG. 5 that the shape of the channel region CHR is a line shape, the shape of the channel region CHR may have a bent shape to secure the length of the channel.

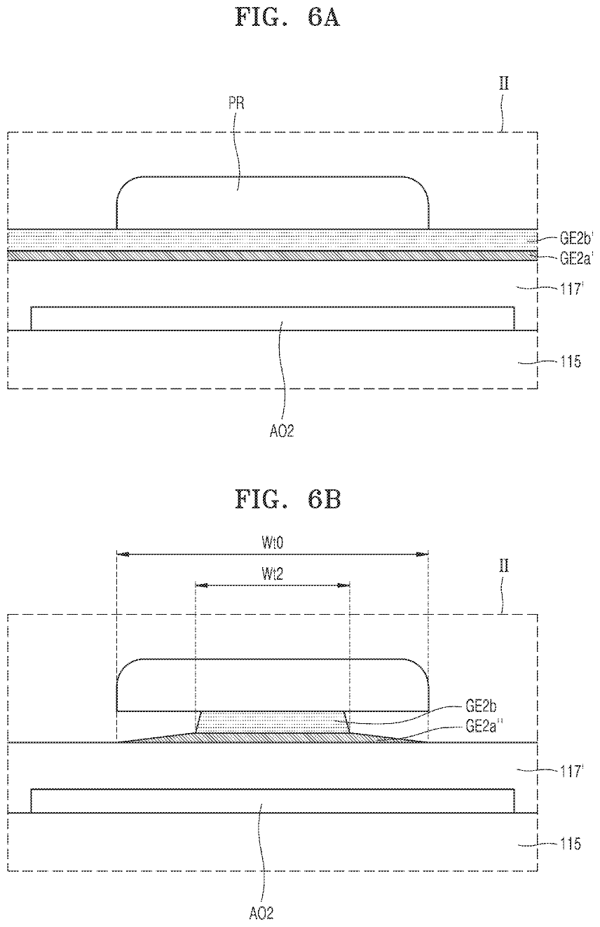

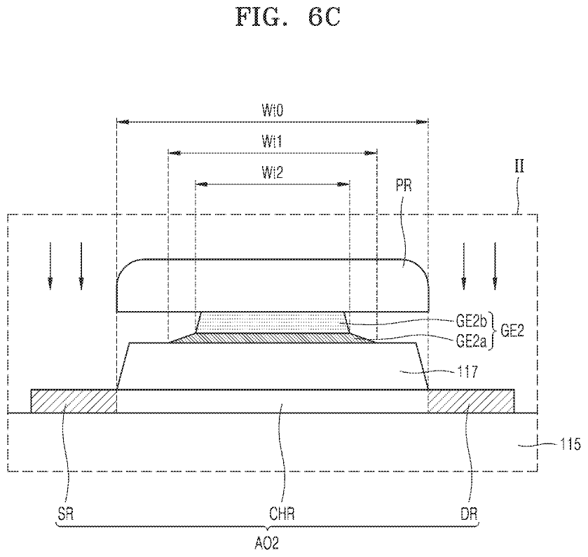

FIGS. 6A, 6B, and 6C are cross-sectional views showing a method of manufacturing a second thin-film transistor according to an embodiment.

Referring to FIG. 6A, the second semiconductor layer AO2 is formed over the substrate, for example, on the second interlayer insulating layer 115. The second semiconductor layer AO2 may include an oxide of at least one of indium (In), gallium (Ga), stannum (Sn), zirconium (Zr), hafnium (Hf), titanium (Ti), and zinc (Zn). In an embodiment, the second semiconductor layer AO2 may include Zn-oxide-based material and include Zn-oxide, In—Zn oxide, and Ga—In—Zn oxide. In an embodiment, the second semiconductor layer AO2 may include an IGZO (In—Ga—Zn—O) semiconductor containing metal such as indium (In) and gallium (Ga) in ZnO.

The second semiconductor layer AO2 is formed through a vapor layer-forming method such as sputtering or a pulse laser deposition method, and photolithography. As an example, a layer including IGZO is formed through a vapor layer-forming method, and then patterned in the shape of the second semiconductor layer AO2. The patterning may include forming, on the layer including IGZO, a photoresist pattern corresponding to portions in which the second semiconductor layer AO2 is to be formed, and then performing wet etching that uses acid solution such as hydrochloric acid, nitric acid, dilute sulfuric acid, or a mixture of phosphoric acid, nitric acid, and acetic acid. In addition, dry etching, or a combination of dry etching and wet etching may be used.

Next, a second gate insulating material layer 117′, a lower material layer GE2a′, and an upper material layer GE2b′ may be sequentially formed on the second interlayer insulating layer 115 to cover the second semiconductor layer AO2.

The second gate insulating material layer 117′ may include an inorganic material including silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) and be formed through chemical vapor deposition (CVD) or atomic layer deposition (ALD).

The lower material layer GE2a′ may include at least one of titanium (Ti) and a titanium (Ti) alloy and be formed through deposition methods such as CVD, plasma enhanced CVD (PECVD), a low pressure CVD (LPCVD), physical vapor deposition (PVD), sputtering, and ALD.

The upper material layer GE2b′ may include at least one of copper (Cu) and a copper (Cu) alloy and be formed through deposition methods such as CVD, plasma enhanced CVD (PECVD), a low pressure CVD (LPCVD), physical vapor deposition (PVD), sputtering, and ALD. The upper material layer GE2b′ may include a material having an etch rate greater than that of the lower material layer GE2a′. In an embodiment, a ratio of an etch rate of the upper material layer GE2b′ and an etch rate of the lower material layer GE2a′ may be about 10:1.

Next, a photoresist pattern PR is formed on the upper material layer GE2b′ through a mask process. In this case, the photoresist pattern PR corresponds to a portion in which the second gate insulating layer 117 is to be formed.

Referring to FIG. 6B, the upper material layer GE2b′ and the lower material layer GE2a′ are primarily formed simultaneously by using, as a mask, the photoresist pattern PR formed on the upper material layer GE2b′. The upper layer GE2b and a preliminary lower layer GE2a″ of the second gate electrode GE2 may be formed through the primary etching.

The primary etching may be wet etching and performed with a condition in which the upper material layer GE2b′ may be over-etched. Accordingly, the width Wt2 of the upper layer GE2b formed while the upper material layer GE2b′ is etched may be less than the width Wt0 of the photoresist pattern PR.

Because an etch rate of the lower material layer GE2a′ is less than an etch rate of the upper material layer GE2b′, the width of the preliminary lower layer GE2a″ formed while the lower material layer GE2a′ is etched may be greater than the width Wt2 of the upper layer GE2b. The width of the preliminary lower layer GE2a″ may be substantially the same as or similar to the width Wt0 of the photoresist pattern PR.

Next, referring to FIG. 6C, a second gate insulating material layer 117′ is secondarily etched by using the photoresist pattern PR as a mask. The second gate insulating layer 117 is formed through the secondary etching. The secondary etching may be dry etching and be performed by using a plasma gas such as CH₄ and SH₆.

The lower layer GE2a of the second gate electrode GE2 may be formed through the secondary etching. That is, a portion of the edge of the preliminary lower layer GE2a″ is etched, and the end of the lower surface of the lower layer GE2a may be apart by the second separation distance d2 from the end of the upper surface of the second gate insulating layer 117. The second separation distance d2 may be in the range of about 0.1 μm to about 1 μm.

In addition, the end of the lower surface of the upper layer GE2b may be apart by about the first separation distance d1 from the end of the upper surface of the lower layer GE2a. The first separation distance d1 may be in the range of about 0.2 μm to about 0.5 μm. The width Wt1 of the lower surface of the lower layer GE2a may be greater than the width Wt2 of the lower surface of the upper layer GE2b and less than the width Wt0 of the second gate insulating layer 117. The width Wt0 of the second gate insulating layer 117 may be substantially the same as or similar to the width Wt0 of the photoresist pattern PR.

The second semiconductor layer AO2 may include an oxide semiconductor as described above. The oxide semiconductor may increase carriers by forming a deficiency state of oxygen. Accordingly, during the dry etching process, the source region SR and the drain region DR may be formed by injecting a plasma gas to a portion of the second semiconductor layer AO2 that is exposed without being covered by the second gate insulating layer 117, and by increasing carrier concentration.

In the present embodiment, because the second gate insulating layer 117 having the width Wt0 greater than the width Wt1 of the lower surface of the second gate electrode GE2 is arranged to correspond to the channel region CHR between the source region SR and the drain region DR, the width of the channel region CHR is greater than the width of the second gate electrode GE2, and thus, a short-channel phenomenon may be prevented from occurring.

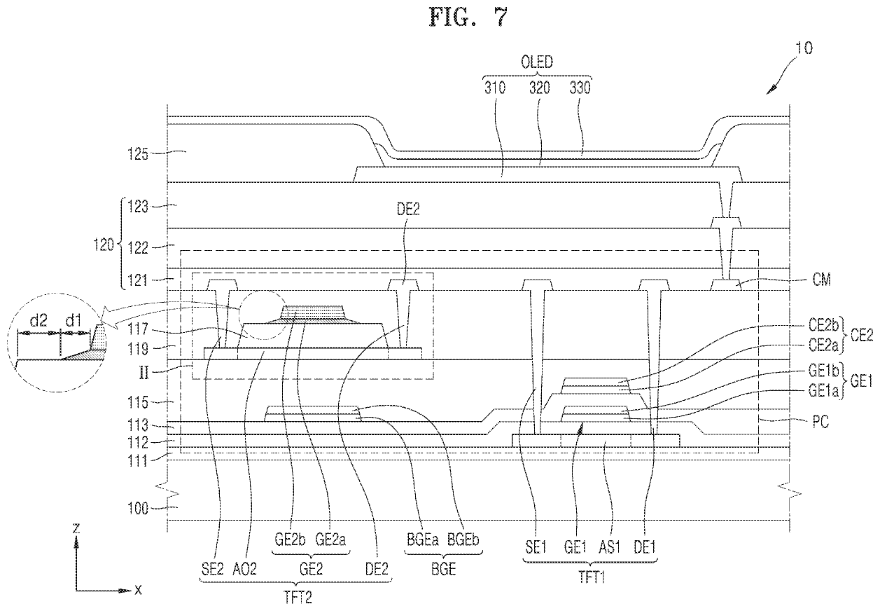

FIG. 7 is a cross-sectional view of a display apparatus according to an embodiment. In FIG. 7, the same reference numerals as those of FIG. 3 denote the same elements, and thus, repeated descriptions thereof are omitted.

Referring to FIG. 7, the display apparatus according to an embodiment may include the first thin-film transistor TFT1 and the second thin-film transistor TFT2 arranged on the substrate 100, the first thin-film transistor TFT1 including a silicon semiconductor, and the second thin-film transistor TFT2 including an oxide semiconductor.

The second thin-film transistor TFT2 may include the second semiconductor layer AO2 and the second gate electrode GE2. The second semiconductor layer AO2 may include an oxide semiconductor, and the second gate electrode GE2 may overlap the second semiconductor layer AO2. The second gate electrode GE2 may have a structure in which the lower layer GE2a and the upper layer GE2b are stacked. The end of the upper surface of the lower layer GE2a may be spaced apart by the first separation distance d1 in the x-direction from the end of the lower surface of the upper layer GE2b. The second gate insulating layer 117 may be arranged between the second semiconductor layer AO2 of the second thin-film transistor TFT2 and the second gate electrode GE2. The end of the upper surface of the second gate insulating layer 117 may be spaced apart by the second separation distance d2 in the x-direction from the end of the lower surface of the second gate electrode GE2.

In an embodiment, the first thin-film transistor TFT1 may include the first semiconductor layer AS1 and the first gate electrode GE1. The first semiconductor layer AS1 may include a silicon semiconductor, and the first gate electrode GE1 may overlap the first semiconductor layer AS1. The first gate electrode GE1 may have a structure in which the first layer GE1a and the second layer GE1b that are stacked. The first layer GE1a may be arranged under the second layer GE1b. That is, the first layer GE1a may be arranged between the first gate insulating layer 112 and the second layer GE1b.

Various wirings may be arranged in the same layer as the first gate electrode GE1, and an interval between the wirings may be narrow due to high integration. Accordingly, it may be advantageous that a tail is not formed in the first gate electrode GE1 and the wirings arranged in the same layer as the first gate electrode GE1. That is, the upper surface of the first layer GE1a may not be exposed by the second layer GE1b. The end of the upper surface of the first layer GE1a may contact the end of the lower surface of the second layer GE1b without being spaced apart from the end of the lower surface of the second layer GE1b. To prevent a tail from being formed in the first gate electrode GE1, an etch rate of the first layer GE1a may be the same as or less than an etch rate of the second layer GE1b.

The first layer GE1a and the second layer GE1b may include a material such that the resistivity of the first gate electrode GE1 is in the range of about 1.8 μΩcm to about 2.2 μΩcm. In addition, the first layer GE1a may include a material having excellent adhesion characteristics with the first gate insulating layer 112. In an embodiment, the first layer GE1a may include a copper (Cu) alloy, and impurities included in the copper alloy may include at least one of Ag, Ca, Zn, Mg, Al, and Ti. In an embodiment, the first layer GE1a may include InZnO. In the case where the first layer GE1a includes InZnO, a ZnO content may be 60 wt % or more. This may be for suppressing the occurrence of the tail of the first layer. The second layer GE1b may include copper (Cu).

Though it is shown in the drawing that the thickness of the first layer GE1a in the y-direction is the same as the thickness of the second layer GE1b in the y-direction, the embodiment is not limited thereto. As an example, the thickness of the second layer GE1b may be greater than the thickness of the first layer GE1a. However, various modifications may be made.

In an embodiment, the second electrode CE2 of the storage capacitor Cst may include a third layer CE2a and a fourth layer CE2b that are stacked, and the bottom gate electrode BGE may include a third layer BGEa and a fourth layer BGEb that are stacked. The third layers CE2a and BGEa may be under the fourth layers CE2b and BGEb, respectively.

The third layers CE2a and BGEa may include a material having excellent adhesion characteristics with the first interlayer insulating layer 113 arranged thereunder. In an embodiment, the third layers CE2a and BGEa may include a copper (Cu) alloy, and impurities included in the copper alloy may include at least one of Ag, Ca, Zn, Mg, Al, and Ti. In an embodiment, the third layers CE2a and BGEa may include InZnO. In the case where the third layers CE2a and BGEa include InZnO, a ZnO content may be 60 wt % or more. This may be for suppressing the occurrence of the tail of the third layers CE2a and BGEa. The fourth layers CE2b and BGEb may include copper (Cu).

Though it is shown in the drawing that the thicknesses of the third layers CE2a and BGEa in the y-direction are the same as the thicknesses of the fourth layers CE2b and BGEb in the y-direction, the embodiment is not limited thereto. As an example, the thicknesses of the fourth layers CE2b and BGEb in the y-direction may be greater than the thicknesses of the third layers CE2a and BGEa in the y-direction. However, various modifications may be made.

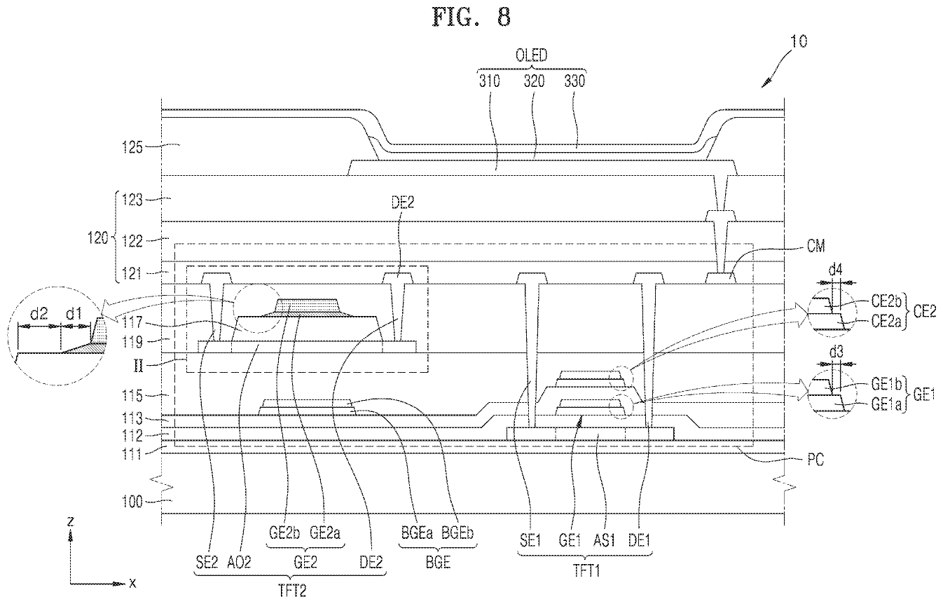

FIG. 8 is a cross-sectional view of a display apparatus according to an embodiment. In FIG. 8, the same reference numerals as those of FIGS. 3, 4, 5, 6, and 7 denote same elements, and, thus, repeated descriptions thereof are omitted.

Referring to FIG. 8, the display apparatus according to an embodiment may include the first thin-film transistor TFT1 and the second thin-film transistor TFT2. The first thin-film transistor TFT1 may include a silicon semiconductor, and the second thin-film transistor TFT2 may include an oxide semiconductor.

The first gate electrode GE1 of the first thin-film transistor TFT1 may have a structure in which the first layer GE1a and the second layer GE1b are stacked. The first layer GE1a may be arranged under the second layer GE1b. That is, the first layer GE1a may be arranged between the first gate insulating layer 112 and the second GE1b.

The first layer GE1a and the second layer GE1b may include a material such that the resistivity of the first gate electrode GE1 is in the range of about 1.8 μΩcm to about 2.2 μΩcm. In addition, the first layer GE1a may include a material having excellent adhesion characteristics with the first gate insulating layer 112.

In an embodiment, the end of the upper surface of the first layer GE1a of the first gate electrode GE1 may be spaced apart by a third separation distance d3 in the x-direction from the end of the lower surface of the second layer GE1b. The third separation distance d3 may have a value in the range of about 0 μm to 0.1 μm. In this case, the third separation distance d3 may be 0.1 μm or less. This means that the tail of the first layer GE1a should be reduced. The third separation distance d3 may be less than the first separation distance d1.

Likewise, the second electrode CE2 of the storage capacitor Cst may have a structure in which the third layer CE2a and the fourth layer CE2b are stacked. The end of the upper surface of the third layer CE2a may be spaced apart by a fourth separation distance d4 in the x-direction from the end of the lower surface of the fourth layer CE2b. In this case, the fourth separation distance d4 may be 0.1 μm or less. This means that the tail of the first layer GE1a should be reduced. The fourth separation distance d4 may be less than the first separation distance d1.

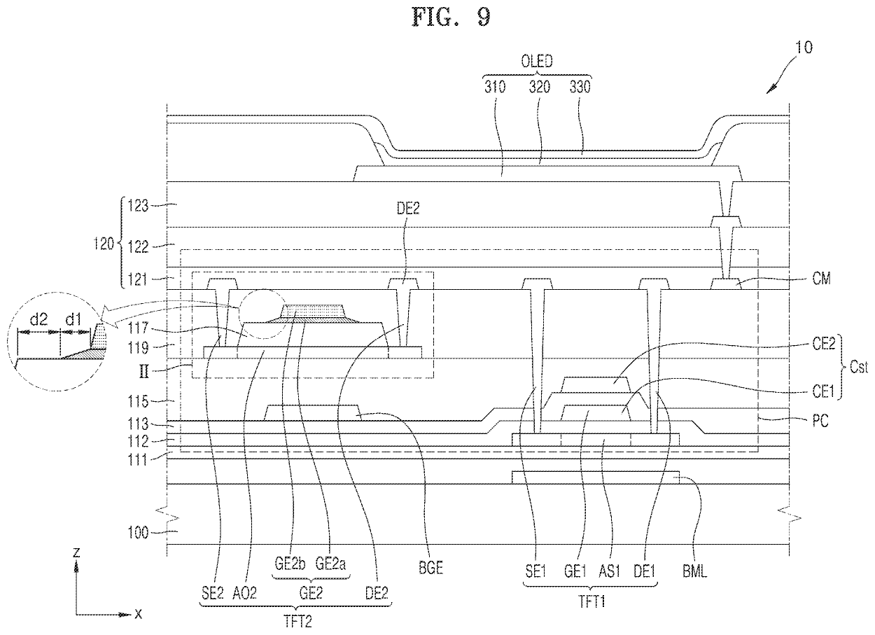

FIG. 9 is a cross-sectional view of a display apparatus according to an embodiment. In FIG. 8, the same reference numerals as those of FIG. 3 denote same elements, and thus, repeated descriptions thereof are omitted.

Referring to FIG. 9, the display apparatus according to an embodiment may include the first thin-film transistor TFT1 and the second thin-film transistor TFT2, the first thin-film transistor TFT1 including a silicon semiconductor, and the second thin-film transistor TFT2 including an oxide semiconductor.

The second thin-film transistor TFT2 may include the second semiconductor layer AO2 and the second gate electrode GE2. The second semiconductor layer AO2 may include an oxide semiconductor, and the second gate electrode GE2 may overlap the second semiconductor layer AO2. The second gate electrode GE2 may have a structure in which the lower layer GE2a and the upper layer GE2b are stacked. The end of the upper surface of the lower layer GE2a may be spaced apart by the first separation distance d1 in the x-direction from the end of the lower surface of the upper layer GE2b. The second gate insulating layer 117 may be arranged between the second semiconductor layer AO2 of the second thin-film transistor TFT2 and the second gate electrode GE2. The end of the upper surface of the second gate insulating layer 117 may be spaced apart by the second separation distance d2 in the x-direction from the end of the lower surface of the second gate electrode GE2.

In the present embodiment, a bottom conductive layer BML may be arranged below the first thin-film transistor TFT1. The bottom conductive layer BML may overlap the first thin-film transistor TFT1. A constant voltage may be applied to the bottom conductive layer BML. Because the bottom conductive layer BML is arranged below the first thin-film transistor TFT1, the first thin-film transistor TFT1 is not less influenced by neighboring interference signals, and reliability thereof may be improved even more.

The bottom conductive layer BML may be arranged between the substrate 100 and the buffer layer 111. The bottom conductive layer BML may include metal or a conductive material.

In an embodiment, the bottom conductive layer BML may include at least one of molybdenum (Mo), aluminum (Al), copper (Cu), and titanium (Ti) and include a single layer or a multi-layer.

In an embodiment, the bottom conductive layer BML may include a transparent conductive material. As an example, the bottom conductive layer BML may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

The bottom conductive layer BML may overlap the first thin-film transistor TFT1, and a constant voltage may be applied to the bottom conductive layer BML. A barrier layer (not shown) may be further arranged between the substrate 100 and the bottom conductive layer BML, the barrier layer blocking the penetration of external air. The barrier layer may include an inorganic material such as oxide or nitride, an organic material, or an organic/inorganic composite material and include a single layer or a multi-layer including an inorganic material and an organic material.

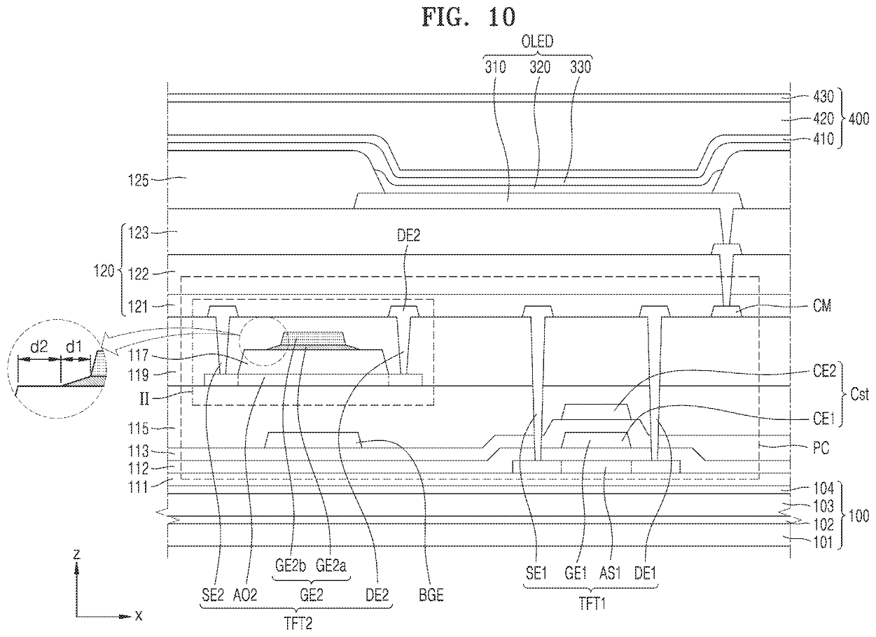

FIG. 10 is a cross-sectional view of a display apparatus according to an embodiment. In FIG. 8, the same reference numerals as those of FIG. 3 denote same elements, and repeated descriptions thereof are omitted.

Referring to FIG. 9, the display apparatus according to an embodiment may include the first thin-film transistor TFT1 and the second thin-film transistor TFT2, the first thin-film transistor TFT1 including a silicon semiconductor, and the second thin-film transistor TFT2 including an oxide semiconductor.

The second thin-film transistor TFT2 may include the second semiconductor layer AO2 and the second gate electrode GE2. The second semiconductor layer AO2 may include an oxide semiconductor, and the second gate electrode GE2 may overlap the second semiconductor layer AO2. The second gate electrode GE2 may have a structure in which the lower layer GE2a and the upper layer GE2b are stacked. The end of the upper surface of the lower layer GE2a may be spaced apart by the first separation distance d1 in the x-direction from the end of the lower surface of the upper layer GE2b. The second gate insulating layer 117 may be arranged between the second semiconductor layer AO2 of the second thin-film transistor TFT2 and the second gate electrode GE2. The end of the upper surface of the second gate insulating layer 117 may be spaced apart by the second separation distance d2 in the x-direction from the end of the lower surface of the second gate electrode GE2.

In the present embodiment, the display apparatus may further include a thin-film encapsulation layer 400 covering the organic light-emitting diode OLED.

The organic light-emitting diode OLED may be easily damaged by external moisture or oxygen and the like, the organic light-emitting diode OLED may be covered and protected by the thin-film encapsulation layer 400. The thin-film encapsulation layer 400 may cover the display area DA and extend to the outside of the display area DA. The thin-film encapsulation layer 400 includes at least one organic encapsulation layer and at least one inorganic encapsulation layer. As an example, the thin-film encapsulation layer 400 may include a first inorganic encapsulation layer 410, an organic encapsulation layer 420, and a second inorganic encapsulation layer 430.

The first inorganic encapsulation layer 410 may cover the opposite electrode 330 and include silicon oxide (SiO₂), silicon nitride (SiNₓ), and silicon oxynitride (SiON). Though not shown, when needed, other layers such as a capping layer may be arranged between the first inorganic encapsulation layer 410 and the opposite electrode 330. Because the first inorganic encapsulation layer 410 is formed along the structure thereunder, the upper surface thereof is not flat. The organic encapsulation layer 420 may cover the first inorganic encapsulation layer 410. Unlike the first inorganic encapsulation layer 410, the organic encapsulation layer 420 may make the upper surface thereof approximately flat. Specifically, the organic encapsulation layer 420 may make a portion of the upper surface thereof approximately flat, the portion corresponding to the display area DA. The organic encapsulation layer 420 may include at least one material from among polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420 and include silicon oxide (SiO₂), silicon nitride (SiNₓ), and silicon oxynitride (SiON).

Even when cracks occurs inside the thin-film encapsulation layer 400, the thin-film encapsulation layer 400 may prevent such cracks from being connected between the first inorganic encapsulation layer 410 and the organic encapsulation layer 420 or between the organic encapsulation layer 420 and the second inorganic encapsulation layer 430 through the above-described multi-layered structure. Through this, a path through which external moisture or oxygen penetrates into the organic light-emitting diode OLED may be prevented or reduced from being formed.

In the present embodiment, the substrate 100 is a flexible substrate and may include a first base layer 101, a first inorganic barrier layer 102, a second base layer 103, and a second inorganic barrier layer 104 that are sequentially stacked. The first base layer 101 and the second base layer 103 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

The first inorganic barrier layer 102 and the second inorganic barrier layer 104 are barrier layers configured to prevent the penetration of impurities, may each include an inorganic material such as silicon oxide (SiO₂), silicon nitride (SiNₓ), and silicon oxynitride (SiON) and have a single-layered structure or a multi-layered structure.

Up to this point, the embodiments applicable to an embodiment have been described. Embodiments may be implemented as separate embodiments or combined embodiments.

A display apparatus according to embodiments may provide a high-quality image even when the display apparatus is highly integrated and driven at high speeds.

Though the above embodiments describe a display apparatus including a thin-film transistor employing an oxide semiconductor and a thin-film transistor employing a silicon semiconductor, the embodiment is not limited thereto. As an example, the display apparatus according to an embodiment may include only a thin-film transistor employing an oxide semiconductor. However, various modifications may be made.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first thin-film transistor arranged on the substrate and including a first semiconductor layer and a first gate electrode, the first semiconductor layer including silicon, and the first gate electrode overlapping the first semiconductor layer;
a second thin-film transistor arranged on the substrate and including a second semiconductor layer and a second gate electrode, the second semiconductor layer including an oxide semiconductor, and the second gate electrode overlapping the second semiconductor layer; and
a display element electrically connected to the first thin-film transistor,
wherein the second gate electrode has a structure in which a lower layer and an upper layer are stacked in a thickness direction, the upper layer including a material different from a material of the lower layer, wherein an end of an upper surface of the lower layer is spaced apart by a first separation distance in a first direction perpendicular to the thickness direction from an end of a lower surface of the upper layer,
wherein a second gate insulating layer patterned is arranged between the second semiconductor layer and the second gate electrode, and wherein an end of an upper surface of the second gate insulating layer is spaced apart by a second separation distance in the first direction from an end of a lower surface of the lower layer.

2. The display apparatus of claim 1, wherein the second separation distance has a value in a range of about 0.2 to about 5 times the first separation distance.

3. The display apparatus of claim 1, wherein the second separation distance has a value in a range of about 0.1 μm to about 1 μm.

4. The display apparatus of claim 1, wherein the first separation distance has a value in a range of about 0.2 μm to about 0.5 μm.

5. The display apparatus of claim 1, wherein a thickness of the upper layer in the thickness direction is greater than a thickness of the lower layer.

6. The display apparatus of claim 1, wherein an etch rate of the upper layer is greater than an etch rate of the lower layer.

7. The display apparatus of claim 1, wherein the upper layer includes copper (Cu), and the lower layer includes titanium (Ti).

8. The display apparatus of claim 1, wherein the first gate electrode includes a single layer of a copper alloy and includes at least one of silver (Ag), calcium (Ca), and zinc (Zn) in addition to copper (Cu).

9. The display apparatus of claim 1, wherein the first gate electrode includes a first layer and a second layer that are stacked in the thickness direction, the second layer is arranged on the first layer, the first layer includes a copper alloy or indium zinc oxide (InZnO), and the second layer includes copper.

10. The display apparatus of claim 9, wherein a end of an upper surface of the first layer contacts an end of a lower surface of the second layer.

11. The display apparatus of claim 9, wherein an end of an upper surface of the first layer is spaced apart by a third separation distance in the first direction from an end of a lower surface of the second layer, and the third separation distance is less than the first separation distance.

12. The display apparatus of claim 11, wherein the third separation distance has a value in a range of about 0 μm to about 0.1 μm.

13. The display apparatus of claim 1, further comprising a storage capacitor overlapping the first thin-film transistor and including a first electrode and a second electrode, the second electrode arranged on the first electrode,
wherein the second electrode includes a third layer and a fourth layer that are stacked in the thickness direction, the fourth layer arranged on the third layer.

14. The display apparatus of claim 13, wherein the third layer includes a copper alloy or indium zinc oxide (InZnO), and the fourth layer includes copper.

15. The display apparatus of claim 1, further comprising a lower conductive layer arranged between the substrate and the first thin-film transistor, wherein the lower conductive layer overlaps at least a portion of the first semiconductor layer.

16. The display apparatus of claim 1, further comprising a thin-film encapsulation layer covering the display element and including a first inorganic encapsulation layer, an organic encapsulation layer, and a second inorganic encapsulation layer that are sequentially stacked in the thickness direction,
wherein the substrate includes a first base layer, a first inorganic barrier layer, a second base layer, and a second inorganic barrier layer that are sequentially stacked in the thickness direction.

17. A display apparatus comprising:
a substrate;
a thin-film transistor arranged on the substrate and including an oxide semiconductor layer and a gate electrode, the oxide semiconductor layer including an oxide semiconductor, and the gate electrode overlapping the oxide semiconductor layer; and
a display element electrically connected to the thin-film transistor,
wherein the gate electrode has a structure in which a lower layer and an upper layer are stacked in a thickness direction, the upper layer including a material different from a material of the lower layer, and an end of an upper surface of the lower layer is apart by a first separation distance from an end of a lower surface of the upper layer,
a gate insulating layer patterned is arranged between the oxide semiconductor layer and the gate electrode, and an end of an upper surface of the gate insulating layer is spaced apart by a second separation distance in a first direction perpendicular to the thickness direction from an end of a lower surface of the lower layer.

18. The display apparatus of claim 17, wherein the second separation distance has a value in a range of about 0.2 to about 5 times the first separation distance.

19. The display apparatus of claim 17, wherein the second separation distance is greater than the first separation distance.

20. The display apparatus of claim 17, wherein the upper layer includes copper (Cu), and the lower layer includes titanium (Ti).
